(19) United States
(12) Patent Application Publication
(10) Pub. No.: US 2026/0134897 A1
(43) Pub. Date: May 14, 2026

(54) SELECTIVE ENABLING AND DISABLING OF SENSE AMPLIFIER CIRCUITRIES IN A MEMORY DEVICE

(71) Applicant: XILINX, INC., San Jose, CA (US)

(72) Inventors: Mrinmoy GOSWAMI, Hyderabad (IN); Kumar RAHUL, Hyderabad (IN); Santosh YACHARENI, Hyderabad (IN); Tabrez ALAM, Hyderabad (IN)

(21) Appl. No.: 18/943,561

(22) Filed: Nov. 11, 2024

(51) Int. Cl. G11C 7/08

(52) U.S. Cl. CPC G11C 7/08

(57) ABSTRACT

A memory device includes memory cells, driver circuitry, and control circuitry. The driver circuitry is connected to the memory cells. The driver circuitry includes first sense amplifier circuitries connected to first memory cells of the memory cells. The second sense amplifier circuitries are connected to second memory cells of the memory cells. The control circuitry enables the first sense amplifier circuitries and disables the second sense amplifier circuitries based on a read command. First data associated with the first memory cells is output via the first sense amplifier circuitries based on the read command.

### TECHNICAL FIELD

Examples of the present disclosure generally relate to a memory device that selective enables and disables sense amplifier circuitries based on read commands.

### BACKGROUND

Memory devices comprise memory cells (or memory bitcells) that store data. The stored data is updated via write operations. The memory cells are organized in columns and rows. During a read command, a row of memory cells associated with the memory address of the read command is activated, and the corresponding data is read. Sense amplifier circuitry associated with the activated cells is used to read and output the data from the activated memory cells.

Configurable memory devices can be full width or multi-port width. In a full width memory device, if the data width is 64 bits, the input/output width is 64 bits. In a multi-port memory device, the data width is not fixed. To meet all of the supported port widths, the memory devices are created to support the lowest granularity of possible port width. In a multi-port memory device, the sense amplifier circuitries, and other circuit elements, are activated even if such circuit elements are not associated with data that is to be read. Accordingly, the amount of power used by and/or the circuit area of such memory devices are increased, increasing the manufacturing cost of the memory device. Thus, there is a need for an improved memory device that is able to selectively activate sense amplifier circuitries that are associated with the data is to be accessed.

### SUMMARY

A memory device includes memory cells, driver circuitry, and control circuitry. The driver circuitry is connected to the memory cells. The driver circuitry includes first sense amplifier circuitries connected to first memory cells of the memory cells. The second sense amplifier circuitries are connected to second memory cells of the memory cells. The control circuitry enables the first sense amplifier circuitries and disables the second sense amplifier circuitries based on a read command. First data associated with the first memory cells is output via the first sense amplifier circuitries based on the read command.

The electronic device includes a processing device that outputs a read command and a memory device connected to the processing device. The memory receives the read command. The memory device includes memory cells and driver circuitry. The driver circuitry is connected to the memory cells. The driver circuitry includes first sense amplifier circuitries connected to first memory cells of the memory cells, and second sense amplifier circuitries connected to second memory cells of the memory cells. The memory device enables the first sense amplifier circuitries and disables the second sense amplifier circuitries based on the read command. First data associated with the first memory cells is output via the first sense amplifier circuitries based on the read command.

In one example, a method includes receiving a read command signal associated with first memory cells of memory cells of a memory device. The first memory cells are connected to first sense amplifier circuitries of sense amplifier circuitries of the memory device, and second memory cells of the memory cells are connected to second sense amplifier circuitries of the sense amplifier circuitries. Further, the method includes enabling the first sense amplifier circuitries and disabling the second sense amplifier circuitries based on the read command signal. The method further includes outputting data associated with the first memory cells via the first sense amplifier circuitries.

These and other aspects may be understood with reference to the following detailed description

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of a memory device.

FIG. 2 illustrates a block diagram of an electronic device.

FIG. 3 illustrates a block diagram of a computer system.

FIG. 4 illustrates a block diagram of a data path of a memory device.

FIG. 5 illustrates a block diagram of a data path of a memory device.

FIG. 6 illustrates a block diagram of control circuitry of a memory device.

FIG. 7 illustrates a block diagram of slice circuitries of a memory device.

FIG. 8 illustrates a block diagram of driver circuitry and control circuitry of a memory device.

FIG. 9 illustrates waveforms used to control a memory device.

FIG. 10 illustrates a block diagram of driver circuitry and control circuitry of a memory device.

FIG. 11 illustrates waveforms used to control a memory device.

FIG. 12 illustrates control circuitry used to generate an enable signal for selectively enabling and disabling sense amplifier circuitries.

FIG. 13 illustrates a flowchart of a method for operating a memory device.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

A memory device includes array of memory cells and input/output circuitry that reads data from and writes data to the memory cells. The input/output circuity includes sense amplifier circuitries that are connected to the memory cells via bitlines and are used to read data from the memory cells. The input/output circuitry may additionally include data write circuitries coupled to the bitlines that are used to write data to the memory cells. A memory device may include multiple memory banks, each memory bank having an array of memory cells. The memory banks are read from and written to by the input/output circuitry.

A memory device is connected to memory controller circuitry that issues (communicates) the memory commands to the memory device. The memory controller circuitry may be part of host device connected to the memory device. In one or more examples, the memory device and the memory controller circuitry are part of the same computer system. The memory commands are read commands and/or write commands. Read commands are used to read data from the memory cells of the memory device. A read command includes a target address within the memory device from where data is to be read. Write commands are used to write data to the memory cells of the memory device. In one example, the memory device receives a read command from the memory controller. The memory device decodes the read command to determine the associated memory address and activates the corresponding memory cells (e.g., a row or another configuration of memory cells). Further, the sense amplifier circuitries are enabled to read and output the data from the activated memory cells.

In some instances, when a read command is issued, all of the sense amplifier circuitries, and supporting circuitries, are activated. However, during a partial read a target address of a read command may only be associated with a portion of the corresponding memory cells. The sense amplifier circuitries that are associated with the memory cells that do not correspond to the target portion of data are activated. As the total read data associated with the sense amplifier circuitries is included the target part of data, the total read data is not used. In one or more instances, data lines associated with one or more memory cells are pre-charged based on a read command. The data lines are pre-charged for memory cells associated with the target address of a read command and for memory cells not associated with the target address of the read command. Thus, activating all of the sense amplifiers and/or pre-charging the data lines for each memory cell increases the power used by the memory device. Increasing the power used by the memory device requires that larger power supplies are incorporated with the memory device and/or increases the corresponding design complexity, increasing the cost of manufacturing the memory device.

In the following, an improved memory device that is able to activate and read from a subset of the sense amplifier circuitries is described. Further, the memory device described herein is able to activate a portion of a data path. The memory device as described herein activates the subset of the sense amplifier circuitries and/or the portion of the data path that is associated with the target address of a read command. For example, a read enable signal is generated based on the read command and used to control which of the sense amplifier circuities are activated and/or which portions of the data path are enabled. Accordingly, a subset of the sense amplifier circuitries and/or a portion of the data path can be dynamically activated (enable) based on a read command, decreasing the amount of power used by the memory device to respond to (e.g., output data associated with) a read command. Thus, the efficiency of the memory device described herein is increased. A memory device as described herein uses less power than that of other memory devices, decreasing the design complexity and manufacturing cost of the memory devices.

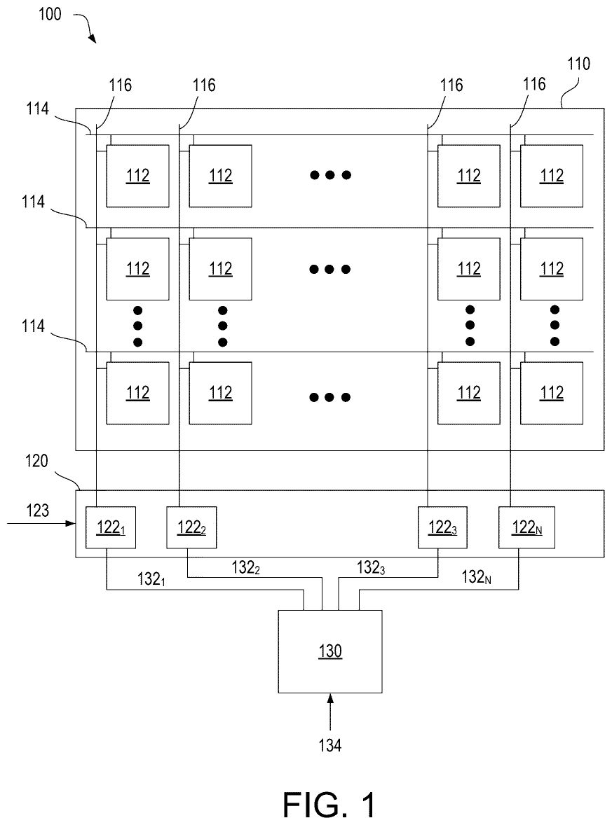

FIG. 1 is a block diagram of a memory device 100. The memory device 100 includes memory cell circuitry 110, driver circuitry 120, and control circuitry 130. The driver (read/write) circuitry 120 is connected to the memory cell circuitry 110. The control circuitry 130 is connected to the driver circuitry 120.

The memory device 100 may be a static random access memory (SRAM). In one or more examples, the memory device 100 is an UltraRAM (URAM) or a Block RAM (BRAM) device. In one example, the memory device 100 is a dynamic RAM (DRAM) device. In other examples, the memory device 100 may be other types of memory devices.

The memory cell circuitry 110 includes memory cells (bitcells) 112. The memory cells 112 store data as voltage values. In one example, a memory cell 112 includes one or more transistors and one or more capacitors that control the activation of a memory cell 112 and the voltage value written in to the bitcell. The memory cells 112 may be disposed in an array. For example, the memory cells 112 are disposed in rows and columns. In one or more examples, the memory cells 112 are disposed in other configurations.

The memory cells 112 are connected to one or more wordlines 114 and one or more bitlines 116. In one example, a wordline 114 is used to active the memory cells 112 connected to the wordline 114. Further, a bitline 116 is used to active the memory cells 112 connected to the bitline 116. In one example, a wordline 114 is driven to a predetermined voltage to activate (select) the corresponding memory cells 112. In one or more examples, a bitline 116 is driven to a predetermined voltage to activate (select) the corresponding memory cells 112. In an example where multiple bitlines 116 are connected to each memory cell 112 (e.g., two bitlines 116 are connected to each column of memory cells 112) a voltage difference is generated between the bitlines 116 to select (activate) the corresponding memory cells 112.

In one example, the wordlines 114 are connected to row driver circuitry (not shown). The row driver circuitry activates one or more of the wordlines 114 by driving a selected one of the wordlines 114 with a predetermined voltage based on the target address of a memory command (e.g., a read command or a write command). In one example, the row driver circuitry receives a memory command, decodes the memory command to determine the row associated with the bitcell or memory cells 112 associated with the target address of the memory command.

The driver circuitry 120 is connected to the memory cells 112 via the bitlines 116. The driver circuitry 120 drives a voltage or voltages onto the bitlines 116 to activate the corresponding memory cells 112. In one example, the driver circuitry 120 receives a memory command, decodes the memory command to determine a target address and memory cells 112 associated with the target address, and drives a voltage or voltages onto the bitline(s) 116 associated with the memory cells 112 that are associated with the target address of the memory command.

In one example, the memory command includes an enable signal 123 that is used to enable elements of the driver circuitry 120. In one example, the driver circuitry 120 includes sense amplifier circuitries 122. The sense amplifier circuitries 122 are connected to the bitlines 116. In one example, a sense amplifier circuitry 122 is connected to a bitline 116 associated with a column (or another grouping) of memory cells 112. In another example, a sense amplifier circuitry 122 is connected to two or more bitlines 116 associated with a column (or another grouping) of memory cells 112.

The sense amplifier circuitry 122 drives a voltage onto a bitline 116 (or bitlines 116) to activate the corresponding memory cells 112.

The control circuitry 130 is connected to the sense amplifier circuitries 122. The control circuitry 130 enables or disables the sense amplifier circuitries 122 via the control signals 132. The control circuitry 130 receives the selection signal or signals 134, and determines the control signals 132 from the selection signal 134. In one example, the control signal(s) 134 include a select signal that indicates which one or more of the sense amplifier circuitries 122 to enable and disable. The selection (control) signals 134 may further include a selection enable signal. In one example, the control signals 132 are generated based on the select signal and the selection enable signal. The select signal(s) 134 may be a binary signal or trinary signal, among others. In other examples, the selection signals 134 include two or more read enable signals, a select enable signal, a clock signal, and a byte-wide enable (WEA) signal. The selection signals 134 may be received from an external memory controller circuitry or processor circuitry connected to the memory device 100.

In one example, the control signal 132₁ is used to enable or disable the sense amplifier circuitry 122₁. The control signal 132₁ is combined with the enable signal 123 to enable, or disable, the sense amplifier circuitry 122₁. The control signal 132₂ is used to enable or disable the sense amplifier circuitry 122₂. The control signal 132₂ is combined with the enable signal 123 to enable, or disable, the sense amplifier circuitry 122₂. The control signal 132₃ is used to enable or disable the source amplifier circuitry 122₃. The control signal 132₃ is combined with the enable signal 123 to enable, or disable, the source amplifier circuitry 122₃. The control signal 132_{N} is used to enable or disable the source amplifier circuitry 122_{N}. N is two or more. The control signal 132_{N} is combined with the enable signal 123 to enable, or disable, the source amplifier circuitry 122_{N}.

In one example, the sense amplifier circuitries 122 are selectively enabled or disabled independently of each other. In one or more examples, a first group of sense amplifiers circuitries 122 is selectively enabled or disabled independently from another group of the sense amplifier circuitries 122. In one example, a first one or more of the sense amplifier circuitries 122 is enabled and a second one or more of the sense amplifier circuitries 122 is disabled. In one example, an enabled source amplifier circuitry, or circuities, 122 correspond to a memory cell 112 that is associated with the target address of the read command. Accordingly, to read and output data from the memory cells 112 based on a read command, not all of the sense amplifier circuitries 122 are enabled, reducing the power used by the memory device 100 to execute and output data corresponding to the read command.

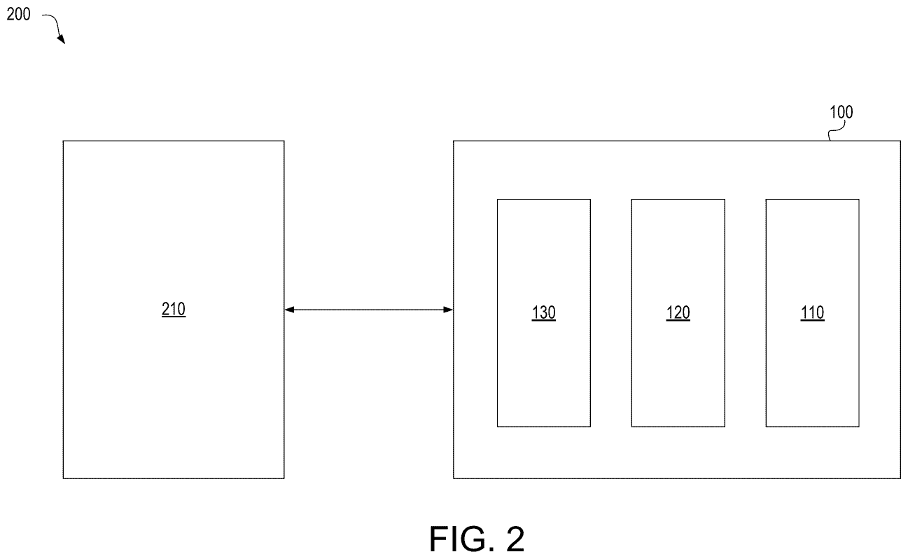

FIG. 2 illustrates a block diagram of an electronic device 200. The electronic device 200 may be included as part of a larger computer system. In on example, the electronic device 200 is a system-on-chip (SoC) device. In one example, the electronic device 200 may include one or more integrated circuit (IC) devices. In one or more examples, the electronic device 200 is an accelerator device included within a computer system. In such an example, the electronic device 200 performs one or more functions of an operation performed by a processing device of the computer system. One or more electronic devices 200 may be included within a computer system.

As illustrated in FIG. 2, the electronic device 200 includes processing device 210 and the memory device 100. The processing device 210 is connected to the memory device 100. In one or more examples, the electronic device 200 includes one or more processing devices 210 and/or one or more memory devices 100. An electronic device 200 is connected to one or more processing devices. The processing device 210 includes or performs the functions of memory controller circuitry. For example, the processing device 210 outputs one or more memory commands (e.g., read commands and/or write commands) to the memory device 100.

The processing device 210 is a field programmable gate array (FPGA) device or an application specific IC (ASIC) device, among others. In one or more examples, the processing device is a central processing unit (CPU) or a graphics processing unit (GPU), among others.

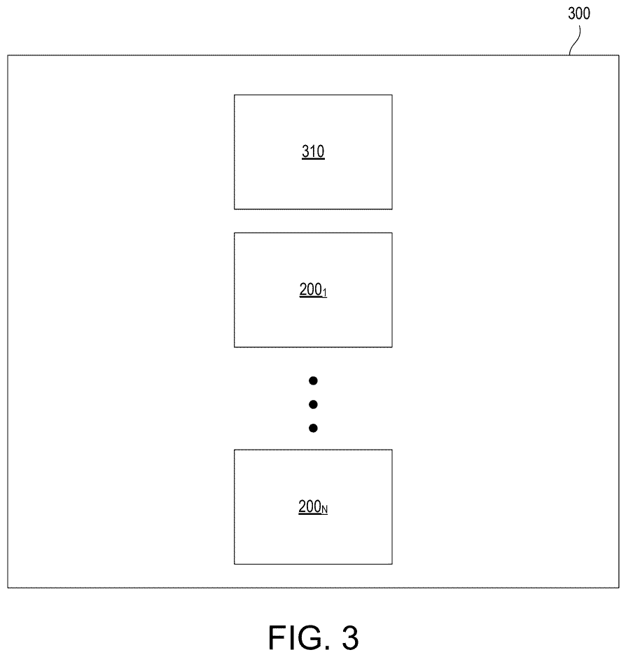

FIG. 3 illustrates a block diagram of a computer system 300. The computer system 300 may be part of a larger distributed computing system. For example, the computer system 300 may be a server device within a larger distributed computing system. In a distributed computing system, the computer system 300 performs one or more functions of an operation performed by the distributed computing system. In a distributed computing system, the computer system 300 is connected to one or more other computer systems via a network connection (e.g., a wired or wireless network connection). In such an example, the computer system 300 includes network circuitry that is used to communicate with the other computer systems. In other examples, the computer system 300 is an individual computer system 300, and not part of a distributed computing system.

The computer system 300 includes a host device 310 and one or more electronic devices 200₁-200_{N}. N is one or more. The host device 310 includes one or more processing devices and/or other circuit devices (e.g., memory controller circuitries and/or input/output circuitries, among others). The host device 310 is connected to the electronic devices 200. The electronic devices 200 may function as accelerator devices, and performs one or more functions with the host device 310 to execute corresponding operations.

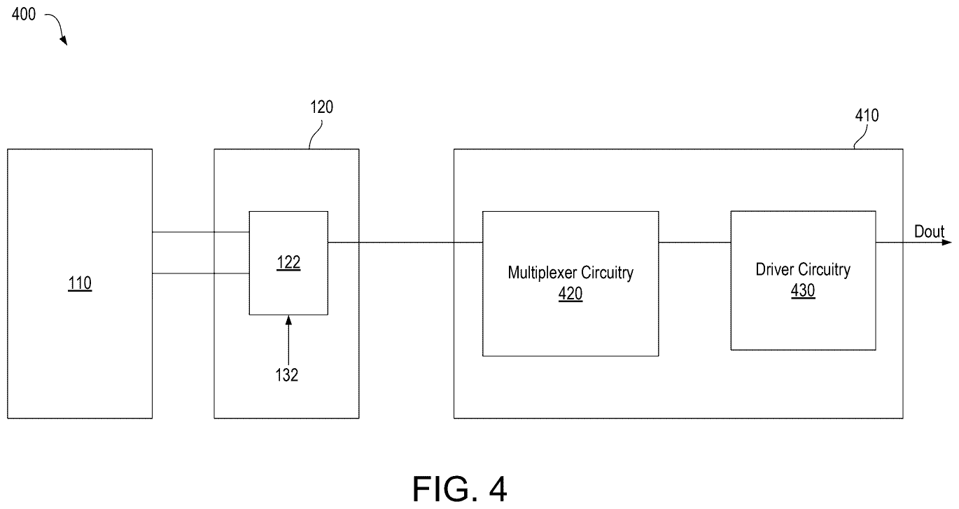

FIG. 4 illustrates a block diagram of a data path circuitry 400. The data path circuitry 400 may be included as part of the memory device 100 of FIG. 1. The data path circuitry 400 includes the memory cell circuitry 110, the driver circuitry 120, and input/output circuitry 410. The memory cell circuitry 110 is connected to the driver circuitry 120, and the input/output circuitry 410 is connected to the driver circuitry 120. In one example, the driver circuitry 120 may be referred to as a local input/output (LIO) circuitry. Further, the input/output circuitry 410 may be referred to as global input/output (GIO) circuitry.

The input/output circuitry 410 includes multiplexer circuitry 420. The multiplexer circuitry 420 controls the selection of memory cell circuitries to be accessed. In one example, the input/output circuitry 410 is connected to one or more memory banks. A memory bank includes one or more memory cell circuitries 110. The multiplexer circuitry 420 may be bank multiplexer circuitry that is connected to the memory banks, and used to select which of the memory banks to access and receive data from. The input/output circuitry 410 further includes driver circuitry 430. The driver circuitry 430 may include latch circuitry and/or other circuit elements that are used to output data. The driver circuitry 430 outputs the signal Dout based on data received from the memory cell circuitry 110. In one example, the output of the driver circuitry 430 is connected to multiplexer circuitry that is external to the data path circuitry 400 and/or external to the corresponding memory device.

In one example, disabling one or more sense amplifier circuitries 122 based on target address of a read command turns off the operation of the disabled sense amplifier circuitries 122 reduces toggling (e.g., operation) of elements within the memory cell circuitry 110, the driver circuitry 120, and/or the input/output circuitry 410, reducing the power used by the corresponding memory system and electronic device.

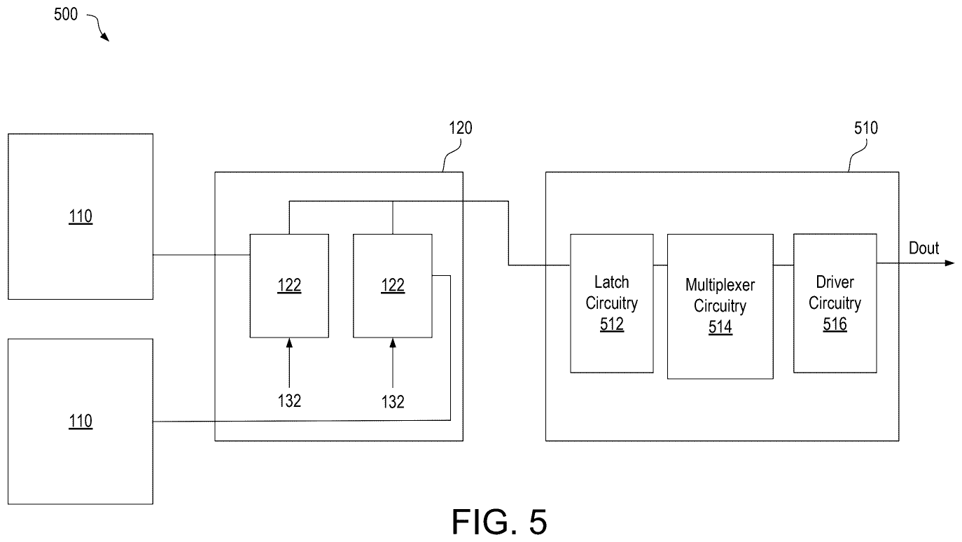

FIG. 5 illustrates a block diagram of data path circuitry 500. The data path circuitry 500 may be included as part of the memory device 100 of FIG. 1. The data path circuitry 500 includes the memory cell circuitries 110, the driver circuitry 120, and input/output circuitry 510. The memory cell circuitries 110 are connected to the driver circuitry 120, and the input/output circuitry 510 is connected to the driver circuitry 120. In one example, the driver circuitry 120 may be referred to as a LIO circuitry. Further, the input/output circuitry 510 may be referred to as GIO circuitry.

The input/output circuitry 510 includes latch circuitry 512, multiplexer circuitry sense, and driver circuitry 516. The latch circuitry 512 receives and stores data from the sense amplifier circuitries 122. The multiplexer circuitry 514 controls the selection of memory cell circuitries to be accessed. The driver circuitry 516 outputs a data signal Dout that corresponds from data read from one or more of the memory cell circuitries 110.

In one example, the input/output circuitry 510 performs a pre-charge operation during the execution of a read command. For example, a pre-charge operation may be performed on a data line (or data lines) between the driver circuitry 120 and the input/output circuitry 510. Further, a pre-charge operation is performed on the bitlines (e.g., the bitlines 116 of FIG. 1) between the driver circuitry 120 and the memory cells (e.g., the memory cells 112 of FIG. 1) that are to be read out based on the target address of a read command. In one example, by selectively activating sense amplifier circuitries 122 based on the target address of a read command, the number of bitlines that are pre-charged are reduced, reducing the power used by the corresponding memory device and/or electronic device.

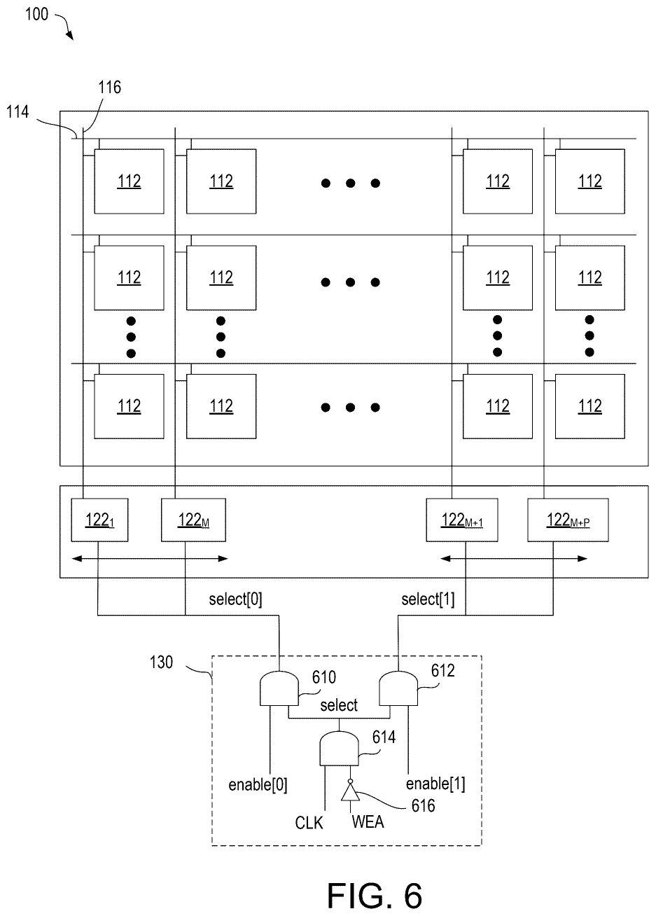

FIG. 6 illustrates an example of the memory device 100, where the control circuitry 130 generates the control signals select[0] and select[1]. The control circuitry 130 in the example of FIG. 6 includes AND gates 610, 612, and 614, and inverter circuitry 616. In other examples, the control circuitry 130 may include other types of logic circuit elements to generate the control signals select[0] and select[1].

The control circuitry 130 receives the enable signals enable[0], enable[1], the clock signal CLK, and the byte-wide write enable signal WEA. The enable signals enable[0] and enable[1] may be received from a processing device (e.g., the processing device 210 of FIG. 2), from a circuit device within the memory device 100, or from another circuit element external to the memory device 100. In one example, the enable signals enable[0] and enable[1] are generated from a memory command. The WEA signal is received from a processing device (e.g., the processing device 210 of FIG. 2), from a circuit device within the memory device 100, or from another circuit element external to the memory device 100. In one example, the clock signal CLK is received from processing device (e.g., the processing device 210 of FIG. 2), from a circuit device within the memory device 100, or from another circuit element external to the memory device 100.

The AND gate 614 receives the clock signal CLK and an inverted version of the WEA signal. The WEA signal is inverted by the inverter circuitry 616. The WEA signal is an enable signal that allows for a read or write operation to occur.

The AND gate 614 generates the select signal based on the clock signal CLK and the inverted WEA signal. In one example, the select signal has a high voltage value (e.g., digital value of 1) based on the clock signal CLK and the inverted WEA signal having high voltage values. The select signal has a low voltage value (e.g., digital value of 0) based on the clock signal CLK and the inverted WEA signal having low voltage values.

The AND gates 610 and 612 have inputs connected to the output of the AND gate 614. The AND gates 610 and 612 receive the select signal from the AND gate 614. The AND gate 610 has an input that receives the enable signal enable[0], and the AND gate 612 has an input that receives the enable signal enable[1]. The AND gate 610 generates and outputs the select signal select[0] based on the enable signal enable[0] and the select signal. The AND gate 612 generates and outputs the select signal select[1] based on the enable signal enable[1] and the select signal.

The select signal select[0] is input to the sense amplifier circuitries 122₁-122_{M}. M is two or more. In one example, M is 8. The select signal select[0] enables or disables the sense amplifier circuitries 122₁-122_{M}. The select signal select[1] is input to the sense driver circuitries 122_{M+1}-122_{M+P}. P is two or more. In one example, P is 8. The select signal select[1] enables or disables the source driver circuitries 122_{M+1}-122_{M+P}.

In one example, the enable signal enable[0] has a high voltage value when the target address of a read command is associated with the memory cells 112 connected to the sense amplifier circuitries 122₁-122_{M}. The enable signal enable[1] has a low voltage value when the target address of a read command is associated with the memory cells 112 connected to the sense amplifier circuitries 122₁-122_{M}. The enable signal enable[1] has a high voltage value when the target address of a read command is associated with the memory cells 112 connected to the source driver circuitries 122_{M+1}-122_{P}. The enable signal enable[0] has a low voltage value when the target address of a read command is associated with the memory cells 112 connected to the source driver circuitries 122_{M+1}-122_{P}.

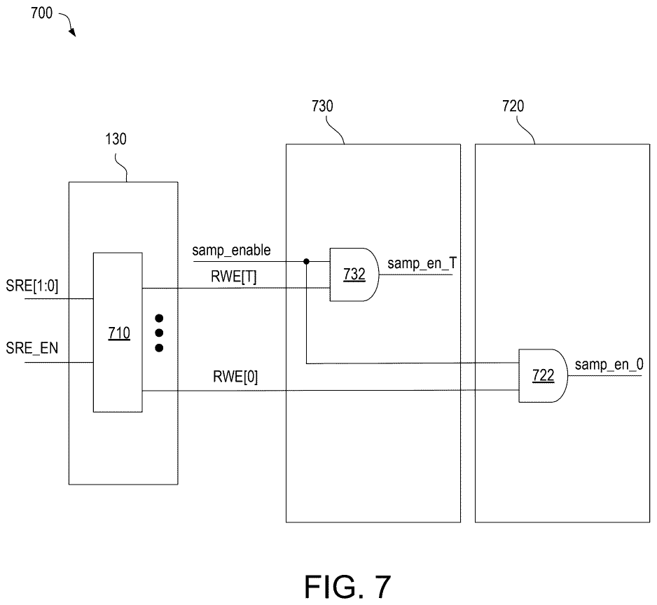

FIG. 7 illustrates a block diagram of a memory device 700. The memory device 700 is configured similar to the memory device 100 of FIG. 1. The memory device 700 includes the control circuitry 130, slice circuitry 720, and slice circuitry 730. In the example of FIG. 7, the control circuitry 130 includes decoder circuitry 710. The decoder circuitry 710 has outputs connected to the slice circuitry 720 and the slice circuitry 730. While FIG. 7 illustrates two slices, in other examples the memory device 700 may include more than two slices (e.g., T slices). A slice circuitry includes sense amplifier circuitries (e.g., the sense amplifier circuitries 122 of FIG. 1) that are connected to and drive memory cells (e.g., the memory cells 112 of FIG. 1).

In one example, the decoder circuitry receives the selective read enable (SRE) select signal SRE[1:0] and the enable signal SRE_EN. The decoder circuitry 710 generates the enable signals RWE[0]-RWE[T] based on the select signal SRE[1:0] and the enable signal SRE_EN. The select signal SRE[1:0] and/or the enable signal SRE_EN is received from a processing device (e.g., the processing device 210 of FIG. 2), a circuit element within the memory device 700, or a circuit element external to the memory device 700. In one example, the select signal SRE[1:0] and/or the enable signal SRE_EN signal is generated from a read command.

The slice circuitry 720 includes AND gate 722. In other examples, the slice circuitry 720 includes other logic elements. The AND gate 722 receives the enable signal RWE[0] from the decoder circuitry 710. Further, the AND gate 722 receives the sense amplifier enable (samp_enable) signal. The samp_enable signal is received from a processing device (e.g., the processing device 210 of FIG. 2), a circuit element within the memory device 700, or a circuit element external to the memory device 700. In one example, the samp_enable signal is generated from a read command.

Based on the samp_enable signal and the enable signal RWE[0], the AND gate 722 generates the enable signal samp_en_0. The enable signal samp_en_0 is input to the sense amplifier circuitries of the slice circuitry 720. The enable signal samp_en_0 enables or disables the sense amplifier circuities of the slice circuitry 720. In one example, the RWE[0] has a high voltage value based on a read command having a target address that is associated with memory cells (e.g., the memory cells 112 of FIG. 1) connected to the slice circuitry 720. Based on the RWE[0] and the samp_enable signal having high values, the enable signal samp_en_0 has a high value, and the sense amplifier circuitries of the slice circuitry 720 are enabled.

The slice circuitry 730 includes AND gate 732. In other examples, the slice circuitry 730 includes other logic elements. The AND gate 732 receives the enable signal RWE[T] from the decoder circuitry 710. Further, the AND gate 732 receives the sense amplifier enable (samp_enable) signal.

Based on the samp_enable signal and the enable signal RWE[T], the AND gate 732 generates the enable signal samp_en_T. The enable signal samp_en_T is input to the sense amplifier circuitries of the slice circuitry 730. The enable signal samp_en_T enables or disables the sense amplifier circuities of the slice circuitry 730. In one example, the RWE[T] has a high voltage value based on a read command having a target address that is associated with memory cells (e.g., the memory cells 112 of FIG. 1) connected to the slice circuitry 730. Based on the RWE[T] and the samp_enable signal having high values, the enable signal samp_en_T has a high value, and sense amplifier circuitries of the slice circuitry 730 are enabled.

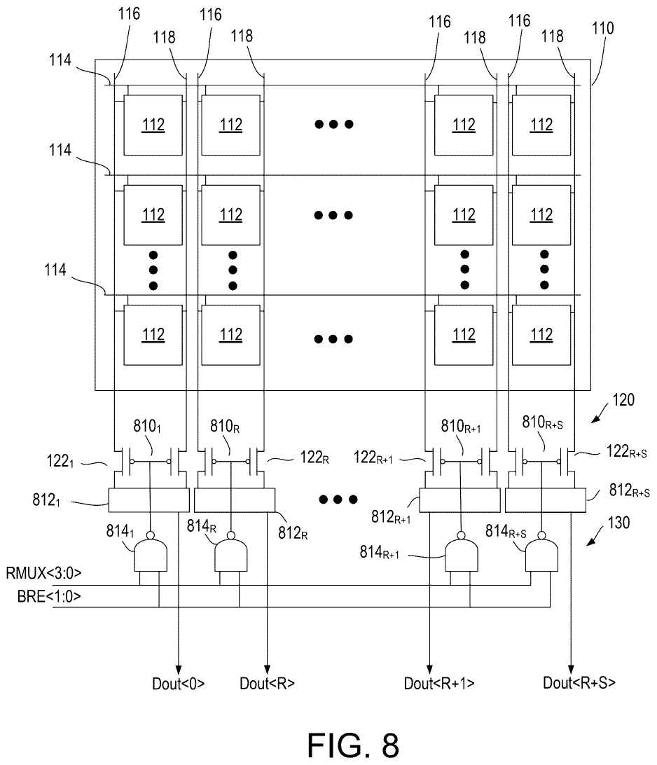

FIG. 8 illustrates the memory device 800. The memory device 800 includes memory cell circuitry 110 and driver circuitry 120. In the example of FIG. 8, the memory cell circuitry 110 further includes bitlines 118. Each of the memory cells 112 is connected to a bitline 116 and a bitline 118. Further, in the example of FIG. 8, each of the sense amplifier circuitries 122 (e.g., sense amplifier circuitries 122₁-122_{R}, and 122_{R+1}-122_{R+S}) include transistor pairs 810. R is two or more. S is two or more. The transistor pairs 810 are connected to the bitlines 116 and 118, and drive the bitlines 116 and 118 to read data associated with corresponding memory cells 112.

In one example, a first transistor of a transistor pair 810 is connected to a bitline 116 and a second transistor of the transistor pair 810 is connected to a bitline 118. In one example, the bitlines 116 and 118 are driven to opposite voltages to read data associated with a corresponding memory cell 112. The sense amplifier circuitries 122 further include driver circuitries 812 that receive the data associated with the memory cells 112 via the bitlines 116 and 118, and output the data from the corresponding memory device. The sense amplifier circuitries 122 output a respective output signal Dout.

The gate nodes of the transistors of in each transistor pair 810 are connected to each other. The gate nodes of the transistors of the transistor pairs 810 are connected to the output of a respective NAND gate 814. In other examples, other types of logic gate circuitries may be used. The NAND gates 814 may be included within the driver circuitry 120 or the control circuitry 130. Each of the NAND gates 814 have an output connected to the gate nodes of respective pairs of the transistor pairs 810. The NAND gates 814 receive the multiplexing signal RMUX<3:0> and the enable signal BRE<1:0>. The multiplexing signal RMUX<3:0> is a multi-bit signal. In one example, the multiplexing signal RMUX<3:0> is a four bit signal. In one example, the enable signal BRE<1:0> is a multi-bit signal. In one example, the enable signal BRE<1:0> is a binary signal. In one example, the multiplexing signal RMUX<3:0> and/or the enable signal BRE<1:0> are received from processing device (e.g., the processing device 210 of FIG. 2), from a circuit device within the memory device 100, or from another circuit element external to the memory device 100. In one example, the multiplexing signal RMUX<3:0> and/or the enable signal BRE<1:0> are received from control circuitry (e.g., the control circuitry 130 of FIG. 1).

The multiplexing signal RMUX<3:0> and the enable signal BRE<1:0> are used to determine which of the sense amplifier circuitries 122 are enabled and which are disabled.

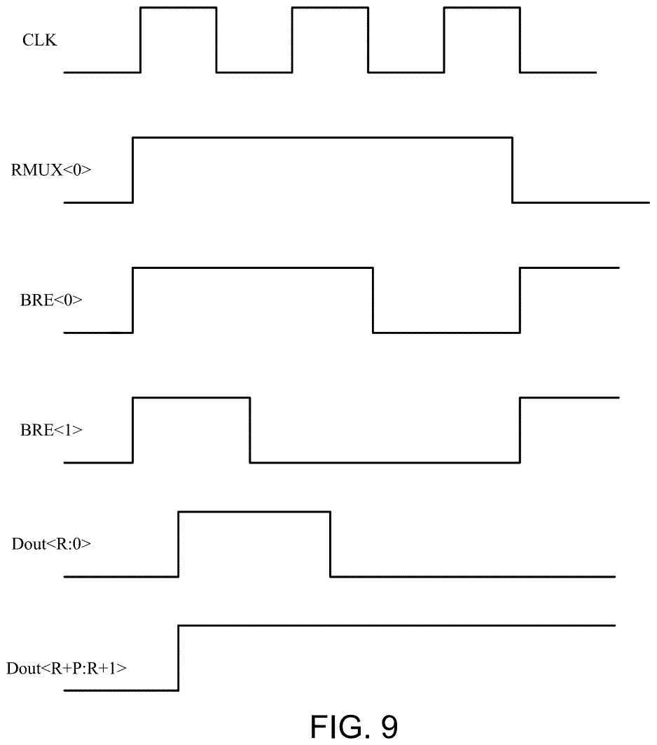

As is illustrated by waveforms of FIG. 9, when the multiplexing signal RMUX and the enable signal BRE<1:0> have a high voltage values, the outputs Dout<0>-Dout<R+S> toggle, and corresponding data is output. Stated another way, all of the sense amplifiers circuitries 122 are enabled when the multiplexing signal RMUX and the enable signal BRE<1:0> have a high voltage values. In an example when the multiplexing signal RMUX and the enable signal BRE<0> have a high voltage values, and the enable signal BRE<1> has a low voltage value, the outputs Dout<0>-Dout<R> toggle, and corresponding data is output. Stated another way, the sense amplifiers 122₁-122_{R} are enabled and the sense amplifiers 122_{R+1} and 122_{R+S} are disabled when the multiplexing signal RMUX and the enable signal BRE<0> have a high voltage values, and the enable signal BRE<1> has a low voltage value. In an example when the multiplexing signal RMUX has a high voltage value and the enable signal BRE<1:0> has a low high voltage value, the outputs Dout<0>-Dout<R+S> do not toggle, and corresponding data is not output. Stated another way, the sense amplifiers 122₁-122_{R+S} are disabled when the multiplexing signal RMUX has a high voltage value and the enable signal BRE<1:0> has a low voltage value.

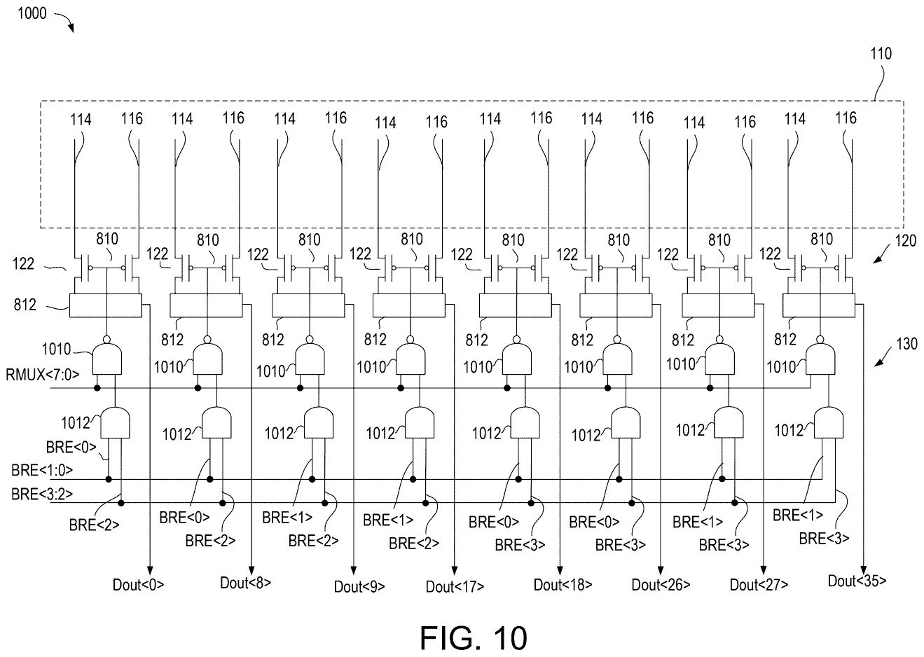

FIG. 10 illustrates a schematic circuit diagram of at least a portion of a memory device 1000. The memory device 1000 is configured similar to the memory device 100 of FIG. 1. As illustrated, the memory device 1000 includes sense amplifier circuitries 122 that include transistor pairs 810 and driver circuitries 812. The memory device 1000 includes NAND gates 1010 and AND gates 1012. The NAND gates 1010 and/or the AND gates 1012 are included in driver circuitry 120 of FIG. 1 or the control circuitry 130 of FIG. 1. In other examples, other types of logic gate circuitries may be used instead of NAND gates and/or AND gates.

In one example, the AND gates 1012 receive the enable signal BRE<1:0> and the enable signal BRE<3:2>. The output of each AND gate 1012 is connected to an input of a respective NAND gates 1010. A second input of each NAND gate 1010 receives the multiplexing signal RMUX<7:0>. The output of each NAND gate 1010 is connected to a gate node of a respective transistor pair 810. In one example, the multiplexing signal RMUX<7:0>, the enable signal BRE<1:0>, and/or the enable signal BRE<3:2> are received from processing device (e.g., the processing device 210 of FIG. 2), from a circuit device within the memory device 100, or from another circuit element external to the memory device 100. In one example, the multiplexing signal RMUX<7:0>, the enable signal BRE<1:0>, and/or the enable signal BRE<3:2> are received from control circuitry (e.g., the control circuitry 130 of FIG. 1).

The use of the multiplexing signal RMUX<7:0>, the enable signal BRE<1:0>, and the enable signal BRE<3:2> allow for the sense amplifier circuitries 122 to be divided into four subsets that can be independently enabled and disabled. Each of the subsets may correspond to one or more bits of data. In one example, each subset corresponds to 9 bits. In other examples, each of the subsets may correspond to more or less than 9 bits.

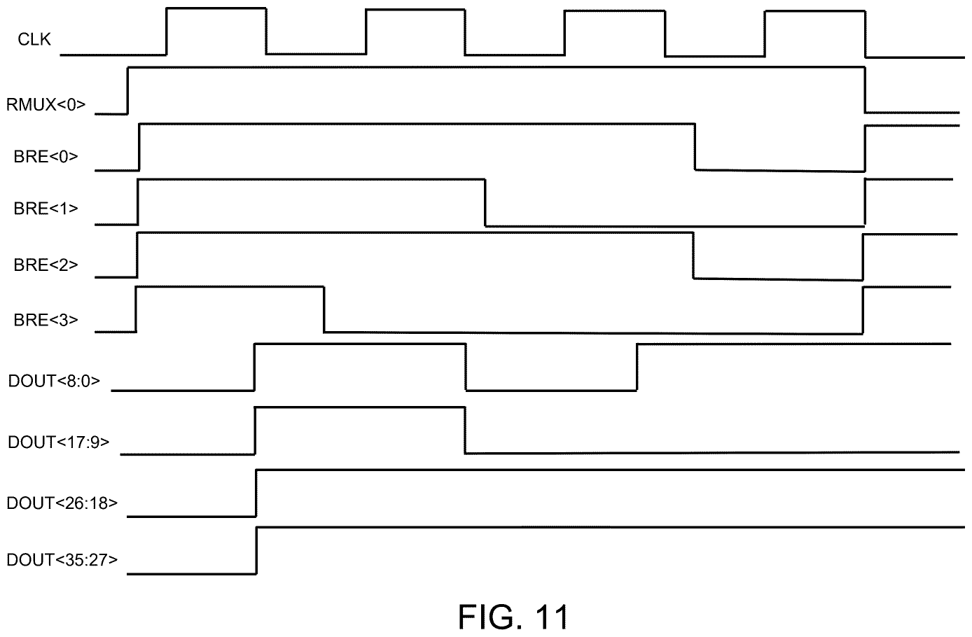

As is illustrated by the waveforms of FIG. 11, when the multiplexing signal RMUX and the enable signal BRE<3:0> have high voltage values, the data outputs Dout<0>-Dout<35> toggle, and data is output from each of the sense amplifier circuitries 122. Based on the multiplexing signal RMUX and the enable signal BRE<3:0> having high voltage values, each of the sense amplifier circuitries 122 are enabled. Such an example corresponds to full port width or a port width of 36.

In one example, when the multiplexing signal RMUX and the enable signal BRE<2:0> have high voltage values, and the enable signal BRE<3> has a low voltage value, the data outputs Dout<0>-Dout<17> toggle, and data is output from each of the sense amplifier circuitries 122. Accordingly, based on the multiplexing signal RMUX and the enable signal BRE<3:0> having high voltage values, and the enable signal BRE<3> has a low voltage value, the sense amplifiers circuitries 122 corresponding to the data outputs Dout<0>-Dout<17> are enabled and the sense amplifier circuitries 122 corresponding to the data outputs Dout<18>-Dout<35> are disabled. Such an example corresponds to a port width of 18 or half port width.

In one example, when the multiplexing signal RMUX and the enable signal BRE<2> have high voltage values, and the enable signals BRE<3> and BRE<1> have a low voltage value, the data outputs Dout<0>-Dout<8> toggle, and data is output from each of the sense amplifier circuitries 122. Accordingly, based on the multiplexing signal RMUX and the enable signal BRE<2> have high voltage values, and the enable signals BRE<3> and BRE<1> have a low voltage value, the sense amplifiers circuitries 122 corresponding to the data outputs Dout<0>-Dout<8> are enabled and the sense amplifier circuitries 122 corresponding to the data outputs Dout<9>-Dout<35> are disabled. Such an example corresponds to a port width of 9 or quarter port width.

In one example, when the multiplexing signal RMUX has a high voltage value and the enable signals BRE<3:0> have low voltage values, the data outputs Dout<0>Dout<35> do not toggle, and data is not output from the sense amplifier circuitries 122. Accordingly, based on the multiplexing signal RMUX has a high voltage value and the enable signals BRE<3:0> have low voltage values, the sense amplifiers circuitries 122 corresponding to the data outputs Dout<0>-Dout<35> are disabled.

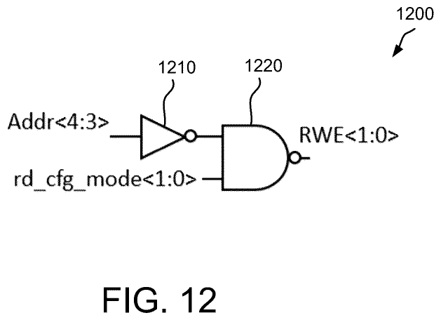

FIG. 12 illustrates control circuitry 1200 that is used to generate the enable signal RWE<1:0>. The control circuitry 1200 may be included as part of the control circuitry 130, the driver circuitry 120, another element of the memory device 100, or external to the memory device 100 (e.g., in an external processing device or host device). The enable signal RWE is used in the memory device 700 of FIG. 7. In one example, the enable signal RWE<1:0> is generated based on an address signal Addr<4:3> and a configuration signal rd_cfc_mode<1:0>. The address signal Addr<4:3> corresponds to a read command. The address signal <4:3> is inverted by the inverter circuitry 1210 and output to the NAND gate 1220. The NAND gate 1220 further receives the configuration signal rd_cfc_mode<1:0>. The NAND gate 1220 outputs the signal RWE<1:0> based on the inverted address signal and the configuration signal rd_cfc_mode<1:0>. In one example, the configuration signal rd_cfc_mode<1:0> corresponds to a port width configuration (e.g., a number of bits to be accessed) of the memory device (e.g., the memory device 100). The configuration signal rd_cfc_mode<1:0> is a multi-bit signal. In one example, the configuration signal rd_cfc_mode<1:0> is a four bit signal. The address signal ADDR<4:3> is a multi-bit signal. In one example, the address signal ADDR<4:3> four bit signal. As is described above with regard to FIG. 7, the enable signal RWE<1:0> is used to determine which of the sense amplifier circuitries are enabled or disabled. As can be seen from the control circuitry 1100 of FIG. 11, changing the value of the configuration signal rd_cfc_mode<1:0> (e.g., changing the port width or data width), changes the number of sense amplifier circuitries that are enabled or disabled. In one or more examples, the number of sense amplifier circuitries that are enabled or disabled is based on a data width configuration mode of the memory device (e.g., the memory device 100 of FIG. 1). The data width configuration mode corresponds to a number of bits of a data width. For example, the data width may be 64 bits. In other examples, the data width is greater than or less than 64 bits. In one examples, the data width configuration mode is set within a register value or other command setting of the memory device via the configuration signal rd_cfc_mode<1:0>.

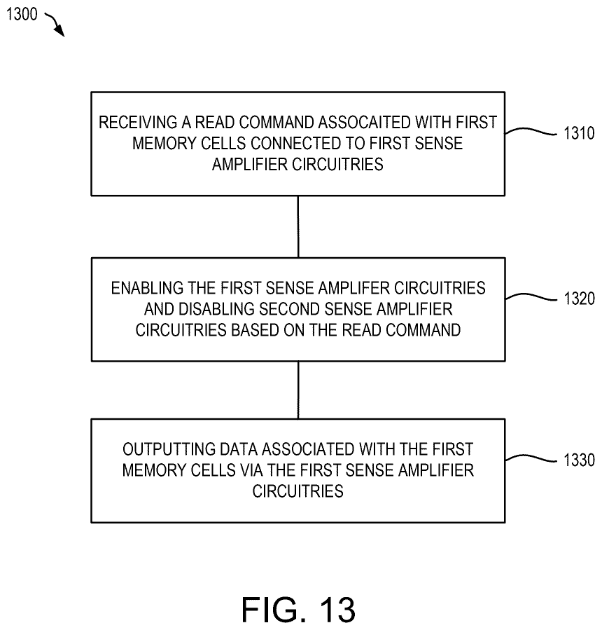

FIG. 13 illustrates a flowchart of a method 1300 for operating a memory device, according to one or more examples. In one example, the method 1300 is performed by a memory device of any of the preceding figures. At 1310 of the method 1300 a read command associated with first memory cells connected to first sense amplifier circuitries is received. In one example, the memory device 100 of FIG. 1 receives the read command. In such an example, the read command is associated with first ones of the memory cells 112.

At 1320 of the method 1300, the first sense amplifier circuitries are enabled and the second sense amplifier circuitries are disabled based on the read command. For example, with reference to the memory device of claim 1, the sense amplifier circuitries 122₁ and 122₂ are enabled and the sense amplifier circuitries 122₃ and 122_{N} are disabled based on the read command signal having a target address associated with a memory cell or memory cells connected to the sense amplifier circuitries 122₁ and/or 122₂.

At 1330 of the method 1300, data associated with the first memory cells is output via the first sense amplifier circuitries. For example, the sense amplifier circuitries 122₁ and 122₂ obtain data from the corresponding memory cells 112 and output the data from the memory device based on the read command.

The memory device as is described in the above selectively activates (enables) and reads from a subset of the sense amplifier circuitries, while other sense amplifier circuitries are disabled. Disabling sense amplifier circuitries reduces the power used by the corresponding memory device. In one example, the subset of sense amplifier circuitries that are selectively activated are connected to the memory cells of the memory device that correspond to the target address of a read command. The selectively activated sense amplifier circuitries obtain data from the corresponding memory cells and the data is output from the memory device.

While the foregoing is directed to specific examples, other and further examples may be devised without departing from the basic scope thereof, and the scope thereof is determined by the claims that follow.

What is claimed is:

1. A memory device comprising:
memory cells;
driver circuitry connected to the memory cells, the driver circuitry comprising:
first sense amplifier circuitries connected to first memory cells of the memory cells;
second sense amplifier circuitries connected to second memory cells of the memory cells; and
control circuitry configured to enable the first sense amplifier circuitries and disable the second sense amplifier circuitries based on a read command, wherein first data associated with the first memory cells is output via the first sense amplifier circuitries based on the read command.

2. The memory device of claim 1, wherein the control circuitry is further configured to generate a first enable signal associated with the read command, and wherein the first enable signal is input to the first sense amplifier circuitries to enable the first sense amplifier circuitries.

3. The memory device of claim 1, wherein the control circuitry is further configured to receive a first selection signal and a first enable signal, generate a second enable signal based on values of the first selection signal and the first enable signal, and output the second enable signal to enable the first sense amplifier circuitries.

4. The memory device of claim 3, wherein the control circuitry is further configured to generate a third enable signal based on the values of the first selection signal and the first enable signal, and output the third enable signal to disable the second sense amplifier circuitries.

5. The memory device of claim 3, wherein the first enable signal corresponds to a port width of the memory device.

6. The memory device of claim 1, enabling the first sense amplifier circuitries is further based on a data width configuration mode of the memory device.

7. The memory device of claim 1, wherein the driver circuitry further comprises third sense amplifier circuitries connected to third memory cells of the memory cells, and wherein the control circuitry is configured to enable or disable the third sense amplifier circuitries based on the read command.

8. An electronic device comprising:
a processing device configured to output a read command; and
a memory device connected to the processing device and configured to receive the read command, the memory device comprising:
memory cells; and
driver circuitry connected to the memory cells, the driver circuitry comprising:
first sense amplifier circuitries connected to first memory cells of the memory cells; and
second sense amplifier circuitries connected to second memory cells of the memory cells, wherein the memory device is configured to enable the first sense amplifier circuitries and disable the second sense amplifier circuitries based on the read command, and wherein first data associated with the first memory cells is output via the first sense amplifier circuitries based on the read command.

9. The electronic device of claim 8, wherein the memory device is further configured to generate a first enable signal associated with the read command, and wherein the first enable signal is output to the first sense amplifier circuitries to enable the first sense amplifier circuitries.

10. The electronic device of claim 8, wherein the memory device is further configured to receive a first selection signal and a first enable signal, generate a second enable signal based on values of the first selection signal and the first enable signal, and output the second enable signal to enable the first sense amplifier circuitries.

11. The electronic device of claim 10, wherein the memory device is further configured to generate a third enable signal based on the values of the first selection signal and the first enable signal, and output the third enable signal to disable the second sense amplifier circuitries.

12. The electronic device of claim 10, wherein the first enable signal corresponds to a port width of the memory device.

13. The electronic device of claim 8, enabling the first sense amplifier circuitries is further based on a data width configuration mode of the memory device.

14. The electronic device of claim 10, wherein the driver circuitry further comprises third sense amplifier circuitries connected to third memory cells of the memory cells, and wherein the driver circuitry is configured to enable or disable the third sense amplifier circuitries based on the read command.

15. A method comprising:
receiving a read command signal associated with first memory cells of memory cells of a memory device, wherein the first memory cells are connected to first sense amplifier circuitries of sense amplifier circuitries of the memory device, and second memory cells of the memory cells are connected to second sense amplifier circuitries of the sense amplifier circuitries;
enabling the first sense amplifier circuitries and disabling the second sense amplifier circuitries based on the read command signal; and
outputting data associated with the first memory cells via the first sense amplifier circuitries.

16. The method of claim 15 further comprising generating a first enable signal associated with the read command signal, and wherein the first enable signal enables the first sense amplifier circuitries.

17. The method of claim 15 further comprising receiving a first selection signal and a first enable signal, generating a second enable signal based on values of the first selection signal and the first enable signal, and outputting the second enable signal to enable the first sense amplifier circuitries.

18. The method of claim 17 further comprising generating a third enable signal based on the values of the first selection signal and the first enable signal, and outputting the third enable signal to disable the second sense amplifier circuitries.

19. The method of claim 17, wherein the first enable signal corresponds to a port width of the memory device.

20. The method of claim 15 further comprising generating a first enable signal to enable the first sense amplifier circuitries based on a data width configuration mode of the memory device.
